(19) United States
(12) Patent Application Publication
(10) Pub. No.: US 2013/0266820 A1
(43) Pub. Date: Oct. 10, 2013

(54) METAL ALLOY COMPOSITIONS AND APPLICATIONS THEREOF

(71) Applicants: Grzegorz Jan Kusinski, Moraga, CA (US); Justin Lee Cheney, San Francisco, CA (US); John Hamilton Madok, San Diego, CA (US)

(72) Inventors: Grzegorz Jan Kusinski, Moraga, CA (US); Justin Lee Cheney, San Francisco, CA (US); John Hamilton Madok, San Diego, CA (US)

(73) Assignee: c/o Chevron Corporation, San Ramon, CA (US)

(21) Appl. No.: 13/440,717

(22) Filed: Apr. 5, 2012

(51) Int. Cl. B32B 15/01; C22C 38/22; C22C 38/12; C22C 38/32; B23K 9/00; C22C 38/18; C23C 4/08; C23C 14/14; B23K 26/20; B23K 10/02; C22C 38/00; C22C 38/04

(52) U.S. Cl. 428/682; 420/8; 420/105; 420/114; 420/110; 420/127; 420/121; 420/120; 420/99; 420/9; 420/10; 420/67; 427/456; 427/597; 219/121.64; 219/121.46; 219/137 R

(57) ABSTRACT

A work piece for use in abrasive environments with hardbanding is provided. The work piece has at least a protective layer deposited onto at least a portion to be protected. The deposited layer exhibits a hardness of at least 50 R_{c}, a wear rate of less than 0.5 grams of mass loss as measured according to ASTM G65-04, Procedure A, a wear rate on a contacting secondary body comprising carbon steel of less than 0.005 grams as measured according to modified ASTM G77 wear test. The deposited alloy forms an iron matrix comprising embedded hard particles in an amount of less than 15 vol. %. The embedded hard particles have an average particle size of ranging from 100 nm to 5 μm. In one embodiment, the deposition is via welding.

### CROSS-REFERENCE TO RELATED APPLICATIONS

NONE

### TECHNICAL FIELD

The invention relates to metal alloys with excellent wear resistant properties suitable for use as coatings in wear-prone environments, and applications employing the alloys for dynamic three-body tribological systems for reduced wear on multiple components of varied hardnesses.

### BACKGROUND

Wear is a problem found in many industries and can encompass different mechanisms. In some applications, there are two different mechanisms of wear, abrasion wear and sliding wear. Under abrasive wear such as in a three-body abrasion system, a third body (e.g., a hard particle such sand) is in contact with two separate primary bodies moving relatively to each other. Under this mechanism, the wear rate is primarily governed by the third body wearing, for example in the form of gouging, chipping, grinding, etc., away at the two respective surfaces of the two primary bodies in motion. The wear rate of each moving primary body is related to the tribological mechanisms between it and the third body, and is relatively independent to the material properties of the opposing primary body. This is in contrast to the mechanisms existing in sliding wear, under which conditions the two primary bodies are in contact with each other and the wear rates of each primary body is directly related to the material properties of the opposing body.

Conditions of abrasive wear can be damaging as they often involve sand, rock particles, or other extremely hard media wearing away against a surface. Applications which see severe abrasive wear in the prior art typically utilize materials of high hardness, 60 R_{c}+, encompassing hard metals or carbides. These materials are often not successful in dealing with conditions of sliding wear, in which wear on both bodies is to be minimized. In cases where one body is significantly harder than the other body, the hard body tends to impart high wear rates on the soft body while wearing significantly less itself. Under applications where one material is a softer material, it is not generally suitable to utilize the prior art materials with high hardness such as carbides or other hard metals.

In certain applications, a material may pass through several different wear mechanisms during its service lifetime. For example, in initial stages of drilling applications, the sides of the drill pipe must rub against the earth, e.g., sand, rock, etc., and is considered a condition of abrasive wear. However, after casing is installed, the sides of the drill pipe now rub against the metal of the casing under conditions of sliding wear. Thus, a difficult scenario emerges where utilizing hard materials reduces abrasive wear, but imparts severe wear on the casing under sliding wear.

Disclosures offering solutions to the competing wear mechanisms in oil & gas drilling applications include but are not limited to U.S. Pat. Nos. 4,277,108; 4,666,797; 6,117,493; 6,326,582; 6,582,126; 7,219,727; and US Patent Publication No. 2002/0054972. US Publication Nos. 2011/0220415 and 2011/004069 disclose an ultra-low friction coating for drill stem assemblies. U.S. Pat. Nos. 6,375,895, 7,361,411, 7,569,286, 20040206726, 20080241584, and 2011/0100720 disclose the use of hard alloys for the competing wear mechanisms. Methods in the prior art to address the competing wear mechanisms include U.S. Pat. No. 7,487,840 and US Patent Publication No. 2006/0102354 for methods to apply a coating on the tool joint. U.S. Pat. No. 6,861,612 discloses a laser beam to deposit a hard coating. US Patent Publication No. 2007/0209839 disclosed an improved drill pipe design. US20060006151A1 discloses the use of amorphous metals for handbanding applications with the injection of pellets into a hard-facing amorphous metal.

In one embodiment, the invention is directed to an improved hardfacing alloy composition, and products with exceptional combination of both high metal to metal wear resistance and resistance to abrasion, e.g., handbanded on tool joints and stabilizers, as well as other industrial products. In another embodiment, the invention is directed to the protection of tool joint and casing components in drilling operations against both abrasive and sliding wear.

### SUMMARY OF THE INVENTION

In one aspect, a work piece capable of withstanding service abrasion is provided. The work piece has at least a portion of its surface protected by a layer comprising an alloy composition having in wt. %: at least one of Cr and Nb of less than 5% each, at least one of Mo and W in an amount of up to 8% each, at least one of B, C, and Si in an amount of 0.5 to 4%, and a total concentration of Cr and Nb of 10%, balance iron, including impurities as trace elements. The layer exhibits a hardness of at least 50 R_{c}, a wear rate of less than 0.5 grams of mass loss as measured according to ASTM G65-04, Procedure A, a wear rate on a contacting secondary body comprising carbon steel of less than 0.005 grams as measured according to modified ASTM G77 wear test.

In a second aspect, a hardbanding for protecting a work piece in an abrasive environment is provided. The hardbanding comprises: a layer comprising an alloy composition having in wt. %: Cr (0-5%), Nb (2-5%), Mn (0-6%), V (0-4%), C (0.25-2%), B (0.75-3%), at least one of Mo and W (3-8% each) and up to 15% total, Ti (0-1%), Si (0-1%), with total concentration of Cr and Nb of up to 10%, total concentration of B, C and Si of up to 4%; and balance iron including impurities as trace elements. The layer is deposited onto at least a portion of the work piece by any of laser welding, shielded metal arc welding (SMAW), stick welding, plasma transfer arc welding (PTAW), gas metal arc-welding (GMAW), metal inert gas welding (MIG), submerged arc welding (SAW), open arc welding (OAW), and combinations thereof. The deposited layer exhibits a hardness of at least 50 Re, a wear rate of less than 0.5 grams of mass loss as measured according to ASTM G65-04, Procedure A, a wear rate on a contacting secondary body comprising carbon steel of less than 0.005 grams as measured according to modified ASTM G77 wear test.

In a third aspect, a method for prolonging a work piece used in an abrasive environment is provided. The method comprises depositing onto at least a surface of the work piece an alloy comprising a composition having in wt. %: at least one of Cr and Nb of less than 5% each, at least one of Mo and W in an amount of up to 8% each, at least one of B, C, and Si in an amount of 0.5 to 4%, and a total concentration of Cr and Nb of 10%, balance iron, including impurities as trace elements. The layer is deposited by any of laser welding, shielded metal arc welding (SMAW), stick welding, plasma transfer arc welding (PTAW), gas metal arc-welding (GMAW), metal inert gas welding (MIG), submerged arc welding (SAW), open arc welding (OAW), and combinations thereof. The deposited alloy exhibits a hardness of at least 50 R_{c}, a wear rate of less than 0.5 grams of mass loss as measured according to ASTM G65-04, Procedure A, a wear rate on a contacting secondary body comprising carbon steel of less than 0.005 grams as measured according to modified ASTM G77 wear test.

### BRIEF DESCRIPTION OF THE DRAWING

FIG. 1A is a diagram illustrating and comparing the wear dynamics between a secondary soft body in a prior art coating comprising a metal alloy with a soft matrix and a microstructure of large hard particles contained within.

FIG. 1B a diagram illustrating the wear dynamics of the secondary soft body in an embodiment of a coating of the invention comprising a metal alloy with a soft matrix but smaller particles in the microstructure.

FIG. 2A is an unmodified optical micrograph showing the microstructure of an embodiment of the metal alloy.

FIG. 2B is a color modified optical micrograph of the microstructure in FIG. 2A.

FIG. 3 is a zoomed-in scanning electron micrograph detailing various specific phases of the metal alloy of FIG. 2A

FIG. 4A is an unmodified optical micrograph showing the microstructure of second embodiment of the metal alloy.

FIG. 4B is a color modified optical micrograph of the microstructure in FIG. 4A.

FIG. 5 is a zoomed-in scanning electron micrograph detailing various specific phases of the metal alloy of FIG. 4A.

FIG. 6A is a diagram showing the schematic of an embodiment of a testing apparatus for use in measuring case wear.

FIG. 6B is a side view of the test apparatus in FIG. 6A.

FIG. 7 is a plot comparing casing wear results as measured using a modified ASTM G77 test for samples of an embodiment of the alloy composition and sample alloys in the prior art.

FIG. 8 is a plot comparing casing wear results (via modified ASTM G77) as well as dry sand abrasion test results (ASTM G65) for the samples in FIG. 7.

### DETAILED DESCRIPTION

The following terms will be used throughout the specification and will have the following meanings unless otherwise indicated.

“Amorphous metal” refers to a metallic material with disordered atomic scale structure. The term can sometimes be used interchangeably with “metallic glass,” or “glassy metal,” or “bulk metallic glass” for amorphous metals having amorphous structure in thick layers of over 1 mm.

Casing is defined as a metal pipe or tube used as a lining for a water, oil, or gas well.

“Coating” is comprised of one or more adjacent layers and any included interfaces. Coating also refers to a layer is placed directly on the substrate of a base body assembly to be protected, or the hardbanding placed on a base substrate material. In another embodiment, “coating” refers to the top protective layer.

A “layer” is a thickness of a material that may serve a specific functional purpose such as reduced coefficient of friction, high stiffness, or mechanical support for overlying layers or protection of underlying layers.

“Hardband” refers to a process to deposit a layer of a special material, e.g., super hard metal, onto drill pipe tool joints, collars and heavy weight pipe in order to protect both the casing and drill string components from wear associated with drilling practices.

“Hardbanding” (or “hardband”) refers to a layer of superhard material to protect at least a portion of the underlying equipment or work piece, e.g., tool joint, from wear such as casing wear. Hardbanding can be applied as an outermost protective layer, or an intermediate layer interposed between the outer surface of the body assembly substrate material and the buttering layer(s), buffer layer, or a coating. Hardbanding may be used interchangeably with “hardfacing,” a term also commonly used by those skilled in the art.

“Coating” may be used interchangeably with “hardbanding,” referring to the layer of superhard material to protect the underlying equipment.

“Hard particles” refer to any of hard boride, carbide, borocarbide particles.

The invention relates to a metal alloy for use in single or multi-stage tribological processes involving multiple bodies of varying hardness, and applications of the metal alloy, e.g., hardbanding applications.

Metal Alloy Composition:

The metal alloy for the hardfacing is characterized as having very fine-grained microstructural features. In one embodiment, the metal alloy comprises an iron-based (ferritic or martensitic) matrix containing fine-scaled hard boride, carbide, borocarbide particles (e.g., M₂B or MC, where M is a transition metal) having average particle sizes of greater than 100 nm and less than 5 μm in an amount of less than 30 vol. %. In another embodiment, the metal alloy is applied as a coating of Fe-based matrix containing fine-scaled hard particles having a volume fraction of less than 15%.

The chromium concentration in the alloy composition is limited to 5 wt. %, as chromium exhibits the tendency to form carbides and borides and can form complex carbides, borides, and boro-carbides including iron due to the very similar atomic sizes between iron and chromium. In one embodiment, the composition further comprises at least an alloying element of larger atomic sizes (compared to Cr) selected from Nb, Mo, and W in an amount of up to 8% each. The concentration of the alloying elements is controlled to help limit the formation of transition metal carbides/borides in the matrix, as inhomogeneous hardness level in the microstructure contributes to uneven wear on the coatings formed therefrom.

In one embodiment, the alloy is an Fe-based alloy having the composition in wt. %: Fe (balance), at least one of Cr and Nb of less than 6% each, at least one of Mo and W in an amount of up to 8% each, at least one of B, C, and Si in an amount of 0.5 to 4%, and a total concentration of Cr and Nb of 11%. In one embodiment, the total concentration of Cr and Nb is 10% or less, and the amount of Cr or Nb is 5% or less.

In another embodiment, the alloy is an Fe-based alloy having the composition in wt. %: Fe (balance), Cr (0-6%), Mn (0-6%), Nb (2-6%), V (0-4%), C (0.25-2%), B (0.75-3%), at least one of Mo and W (3-8% each) up to 15% total, Ti (0-1%), Si (0-1%), with the total concentration of Cr and Nb of up to 11% and total of B, C and Si of up to 4%.

In yet another embodiment, the composition contains in wt. %: Fe (balance), Cr (0-6%), Mn (0-1%), Nb (4-6%), V (0.5-3%), C (0-1%), B (1-3%), at least one of Mo and W (0-8% each) up to 15% total, Ti (0-0.25%), and Si (0-0.75%), with the total concentration of Cr and Nb of up to 11% and total of B, C and Si of up to 4%.

In a fourth embodiment, the composition contains: Fe (balance), Cr (0-6%), Mn (0-1%), Nb (4-6%), V (0-1%), C (0-0.5%), B (2-3%), at least one of Mo and W (2-8% each) up to 10% total, Ti (0-0.25%), and Si (0-0.25%), with the total concentration of Cr and Nb of up to 11% and total of B, C and Si of up to 4%.

In a fifth embodiment, the alloy is any of the followings in wt. %, with the total concentration of Cr and Nb of up to 11% and total of B, C and Si of up to 4%:

Alloy 1: Fe (82.68%), Cr (5%), Nb (4.3%), V (0.5%), C (0.8%), B (2.5%), Mo (3%), Mn (0.5%), Ti (0.2%), and Si(0.5%);

Alloy 2: Fe (82.68%), Cr (5%), Nb (4.3%), V (0.5%), C (0.8%), B (2.5%), Mo (3%), Mn (0.5%), Ti (0.2%), and Si (0.5%);

Alloy 3: Fe (80.4%), Cr (5.6%), Nb (4.4%), V (0.6%), C (0.5%), B (1.7%), W (6.6%), Ti (0.2%);

Alloy 4: Fe (81%), Cr (5.6%), Nb (4.4%), V (0.6%), C (0.5%), B (1.1%), W (6.6%), Ti (0.2%);

Alloy 5: Fe (83.93%), Cr (5%), Nb (4.3%), V (0.5%), C (0.8%), B (1.25%), W (3%), Mn (0.5%), Ti (0.2%), Si (0.5%);

Alloy 6: Fe (82.66%), Cr (5%), Nb (4.3%), V (0.5%), C (1%), B (0.82%), W (5%), Ti (0.2%), Si (0.52%);

Alloy 7: Fe (79.8%), Cr (5%), Nb (4.3%), C (0.5%), B (2.5%), W (7.5%), Ti (0.25%), Si (0.15%);

Alloy 8: Fe (79.3%), Cr (5%), Nb (4.3%), V (0.5%), C (0.5%), B (2.5%), W (7.5%), Ti (0.25%), Si (0.15%);

Alloy 9: Fe (80.3%), Cr (5%), Nb (4.3%), V (0.5%), C (0.5%), B (2.5%), W (6.5%), Ti (0.25%), Si (0.15%);

Alloy 10: Fe (83.68%), Cr (4%), Nb (4.3%), V (0.5%), C (0.8%), B (2.5%), Mo (3%), Mn (0.5%), Ti (0.2%), Si (0.5%);

Alloy 11: Fe (84.68%), Cr (3%), Nb (4.3%), V (0.5%), C (0.8%), B (2.5%), Mo (3%), Mn (0.5%), Ti (0.2%), Si (0.5%);

Alloy 12: Fe (85.68%), Cr (2%), Nb (4.3%), V (0.5%), C (0.8%), B (2.5%), Mo (3%), Mn (0.5%), Ti (0.2%), Si (0.5%);

Alloy 13: Fe (86.68%), Cr (1%), Nb (4.3%), V (0.5%), C (0.8%), B (2.5%), Mo (3%), Mn (0.5%), Ti (0.2%), Si (0.5%);

Alloy 14: Fe (87.68%), Cr (0%), Nb (4.3%), V (0.5%), C (0.8%), B (2.5%), Mo (3%), Mn (0.5%), Ti (0.2%), Si (0.5%);

Alloy 15: Fe (82.18%), Cr (5%), Nb (4.3%), V (0.5%), C (0.8%), B (2.5%), Mo (3%), Mn (1%), Ti (0.2%), Si (0.5%);

Alloy 16: Fe (83.18%), Cr (4%), Nb (4.3%), V (0.5%), C (0.8%), B (2.5%), Mo (3%), Mn (1%), Ti (0.2%), Si (0.5%);

Alloy 17: Fe (84.18%), Cr (3%), Nb (4.3%), V (0.5%), C (0.8%), B (2.5%), Mo (3%), Mn (1%), Ti (0.2%), Si (0.5%);

Alloy 18: Fe (85.18%), Cr (2%), Nb (4.3%), V (0.5%), C (0.8%), B (2.5%), Mo (3%), Mn (1%), Ti (0.2%), Si (0.5%);

Alloy 19: Fe (86.18%), Cr (1%), Nb (4.3%), V (0.5%), C (0.8%), B (2.5%), Mo (3%), Mn (1%), Ti (0.2%), Si (0.5%);

Alloy 20: Fe (87.18%), Cr (0%), Nb (4.3%), V (0.5%), C (0.8%), B (2.5%), Mo (3%), Mn (1%), Ti (0.2%), Si (0.5%);

Alloy 21: Fe (81.68%), Cr (5%), Nb (4.3%), V (0.5%), C (0.8%), B (2.5%), Mo (3%), Mn (1.5%), Ti (0.2%), Si (0.5%);

Alloy 22: Fe (82.68%), Cr (4%), Nb (4.3%), V (0.5%), C (0.8%), B (2.5%), Mo (3%), Mn (1.5%), Ti (0.2%), Si (0.5%);

Alloy 23: Fe (83.68%), Cr (3

%), Nb (4.3%), V (0.5%), C (0.8%), B (2.5%), Mo (3%), Mn (1.5%), Ti (0.2%), Si (0.5%);

Alloy 24: Fe (84.68%), Cr (2%), Nb (4.3%), V (0.5%), C (0.8%), B (2.5%), Mo (3%), Mn (1.5%), Ti (0.2%), Si (0.5%);

Alloy 25: Fe (85.68%), Cr (1%), Nb (4.3%), V (0.5%), C (0.8%), B (2.5%), Mo (3%), Mn (1.5%), Ti (0.2%), Si (0.5%); and

Alloy 26: Fe (86.68%), Cr (0%), Nb (4.3%), V (0.5%), C (0.8%), B (2.5%), Mo (3%), Mn (1.5%), Ti (0.2%), Si (0.5%).

The alloy incorporates the above elemental constituents a total of 100 wt. %. In some embodiment, the alloy may include, may be limited to, or may consist essentially of the above named elements. In one embodiment, the alloy may include 2% or less of impurities. Impurities may be understood as elements or compositions that may be included in the alloys due to inclusion in the feedstock components, through introduction in the processing equipment, or by reaction of the alloy compositions with the environment.

After deposition on a substrate, the alloy forms a protective coating having iron rich phases containing embedded hard particles (carbides, borides, and/or borocarbides). In one embodiment, the boride phase is represented as M₂B, wherein M is a transition metal. In one embodiment, the embedded hard particles in the ferritic matrix contain Nb, Cr, and Mo/W with both carbon and/or boron. In another embodiment, the particles are in the form of embedded Nb carbide and Mo-boro carbide precipitate.

The fine grained hard particles have an average size of 100 nm-20 μm in one embodiment; from 1 to 15 μm in a second embodiment; from 5-10 μm in a third embodiment; and less than 5 μm in a fourth embodiment. The hard particles greater than 100 nm are present in an amount of less than 15 vol. % in one embodiment; less than 10 vol. % in a second embodiment; less than 5 vol. % in a third embodiment; and less than 1 vol. % in a fourth embodiment. In one embodiment, more than 50% of the hard particles are Nb carbide precipitates having a particle size of 0.5 to 1 μm.

In one embodiment, the coatings formed from the alloy compositions are characterized as having a relatively uniformly hard microstructure, with precipitates of the same type having particle sizes with standard deviations of less than 25%. The more uniform microstructure allows for a more uniform wear rate across the coating surface. Additionally, the coatings are subject to slower wear rate compared to coatings of the prior art having larger grain sizes (e.g., 200 nm to 5 μm or from 0.5-3 μm).

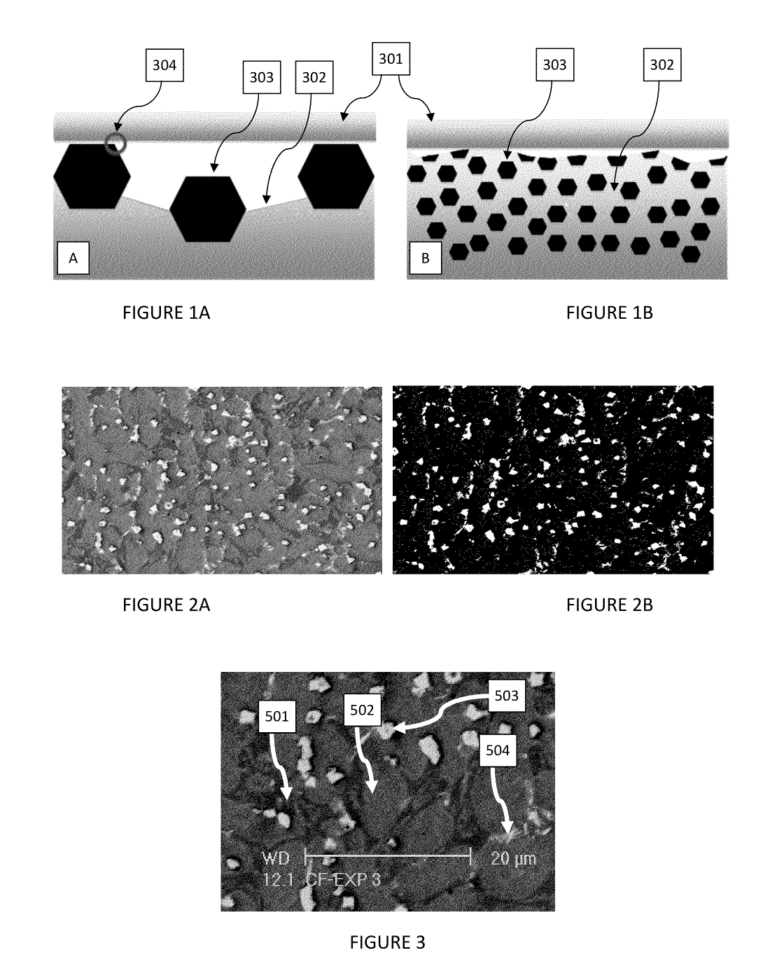

As illustrated in FIGS. 1A-1B, “large” hard particles (>100 nm) result in uneven wear mechanism (A) as compared to an embodiment of the invention with a “fine-grained” alloy microstructure (B). Both amorphous metal alloys can be characterized as having hard (>50 R_{c}) weldments and cast components with compositions comprising a relatively softer matrix with embedded hard particles. However, in a coating with the “large-grained” alloy of FIG. 1A, the softer matrix [302] is worn away at a much faster rate than the hard [303] particles when the alloy comes into contact with softer secondary bodies [301], exposing the hard particles [303] and effectively forming a rough wear surface [304]. In FIG. 1B for an embodiment of a coating of the invention with smaller hard particles [303] microstructure, the smaller hard particles tend to wear away in a smoother profile, limiting the potential for aggressive wear on the softer secondary bodies [301].

Method for Forming Hardbanding:

In one embodiment, the alloy may be formed by blending various feedstock materials together, which may then be melted in a hearth or furnace and formed into ingots. The ingots can be re-melted and flipped one or more times, which may increase homogeneity of the ingots. Combinations of powders may be contained in conventional steel sheaths, which when melted may provide the targeted alloy composition. The steel sheaths may include plain carbon steel, low, medium, or high carbon steel, low alloy steel, or stainless steel sheaths.

The ingots may then be melted and atomized or otherwise formed into an intermediate or final product. The forming process may occur in a relatively inert environment, including an inert gas. Inert gasses may include, for example, argon or helium. If atomized, the alloy may be atomized by centrifugal, gas, or water atomization to produce powders of various sizes, which may be applied to a surface to provide a hard surface.

The alloys may be provided in the form of stick, wire, powder, cored wire, etc. In one embodiment, the alloys are formed into a stick electrode, e.g., a wire, of various diameters, e.g., 1-5 mm. In some embodiments, the cored wire may contain flux, which may allow for welding without a cover gas without porosity-forming in the weld deposit.

In one embodiment, the metal alloys are applied onto a surface using techniques including but not limited to thermal spray coating, weld-overlay, laser cladding, and combinations thereof. In another embodiment, the alloys are deposited in the form of wire feedstock employing hardfacing/welding techniques known in the art. The alloys can be applied with mobile or fixed, semi or automatic welding equipment. In one embodiment, the alloys are applied using any of laser welding, shielded metal arc welding (SMAW), stick welding, plasma transfer arc welding (PTAW), gas metal arc-welding (GMAW), metal inert gas welding (MIG), submerged arc welding (SAW), or open arc welding (OAW).

In one embodiment, the alloy is deposited onto a machined surface or alternatively, a surface blast cleaned to white metal (e.g., ISO 8501-1). The depth of the machined surface is grooved for flush type application depends on the welding applicator. In one embodiment for application on a used pipe, the existing hardbanding is first completely removed by gouging, grinding, or using other suitable techniques.

In one embodiment, the surfaces for deposition are first preheated at a temperature of 275° C. or greater, e.g., 275-500° C., for 0.01 hours to 100 hours. In one embodiment, the preheat may reduce or prevent cracking of the deposited welds.

The alloy may be applied to a surface in one or more layers as an overlay. In one embodiment, each layer having an individual thickness of 1 mm to 10 mm. In one embodiment, the overlay has a total thickness of 1 to 30 mm. In one embodiment, the width of the individual hard-band ranges from 5 mm to 40 m. In another embodiment, the width of the total weld overlay ranges from 5 mm to 20 feet.

After deposition on a substrate, the alloy is allowed to cool to form a protective coating. In one embodiment, the cooling rate ranges from 100 to 5000 K/s, a rate sufficient for the alloy to produce iron rich phases containing embedded hard particles (e.g., carbides, borides, and/or borocarbides).

Grain coarsening is known stage in the growth process of crystals during solidification. In the prior art compositions, the hard phase will begin to nucleate and grow before the matrix phase during the solidification of the alloy. The extended growth period of the hard phases, as compared to that of the matrix, can result in high fraction (e.g., greater than 15%) of larger hard particles in the microstructure. These larger hard particles, while beneficially impacting the alloy durability, contribute to additional casing wear in a manner independent of the grain size of the matrix.

As opposed to alloy compositions in the prior art, the growth period of the hard phases in the inventive composition is suppressed or sluggish for a growth mechanism similar to that of ferrite. This causes the growth of both ferrite phase and hard-particle phases to be more closely matched during the solidification, resulting a small fraction of hard particles exceeding 100 nm in size. By controlling the nucleation, growth thermodynamics and kinetics as a function of the alloy composition, the ferritic matrix and hard particles in the alloy solidify according to independent mechanisms, resulting in a microstructure consisting of very fine grained hard particles, which are uniformly distributed. This microstructural property imparts uniformity to the micro-hardness of the alloy, which contributes to both enhanced durability and reduced casing wear.

The microstructure has a hardness variation of less than 50% as measured using a Vickers indenter between fine grained hard particles and the surrounding matrix in one embodiment; less than 25% in a second embodiment; and less than 15% in a third embodiment. The measured Vickers hardnesses within a cross sectional area of 100 μm×100 μm in the weld bead have a standard deviation below 250 in one embodiment; less than 150 in a second embodiment; and less than 100 in a third embodiment.

Properties:

Generally in the field of hardbanding, high durability is inversely proportional to low casing wear. However, as the growth of hard particles in the microstructure is minimized, the metal alloy surfaces possess a unique combination of: 1) high hardness, high durability, and 2) creates minimal wear on a contacting softer counter body in conditions of sliding wear (e.g., casing wear in the field hardbanding).

In one embodiment, a work piece having at least a portion of its surface having a coating or a welded layer of the metal alloy with the fine-grained microstructure is characterized as having a macro-hardness as measured via standard Rockwell C test of greater 50_{Rc} in one embodiment; a macro-hardness in the range of 52-60_{Rc} in a second embodiment; and a hardness of at least 55_{Rc} in a third embodiment.

When applied as coatings, e.g., hardbanding, for protection of work pieces, the fine-grained microstructural features in the alloy provide durability and prevent wear on secondary “softer” bodies which come into contact with the work piece protected by the coatings. The component protected by the alloy is characterized as having elevated wear resistance with a dry sand abrasion mass loss (ASTM G65-04 procedure A) of less than 0.5 grams in one embodiment; and less than 0.35 grams in a second embodiment. Furthermore, the elevated wear resistance does not result in significant wear loss on a contacting secondary body, as characterized by a mineral oil metal to metal sliding wear materials loss on the secondary body (modified ASTM G77 wear test) of less than 0.005 grams when the secondary body is a plain carbon steel. In one embodiment, the wear loss on a contacting secondary body comprising carbon steel is less than 0.001 g as measured according to modified ASTM G77 wear test.

FIG. 6A is a diagram illustrating the ASTM G77 wear test and apparatus for use in the modified test to measure material loss on a secondary body. In this test method, the tool joint material is held against the casing ring at a prescribed side load of 5,000 lb/ft. The tool joint has a weld overlay coating on the contacting surface of the casing, simulating a hardband for oil and gas downhole wear protection. The casing ring is fabricated according to the API Q125 specification and rotates at 197 rpm for 21,600 rotations.

As shown in the side view diagram of FIG. 6B, the bottom half of the casing is submerged in mineral oil, which is drawn up the surface of the casing ring and acts as lubrication in the test. Mineral oil is used to simulate oil-based drilling muds simulate in the downhole environment. Because it is desired to understand the wear contribution of solely the tool joint and or hardbanding layer on the wear of the casing, oil-based drilling mud is not used to characterize the materials in this modified test. The drilling mud, as it contains sand, would add an additional wear contribution to the casing and affect the accuracy and understanding of the wear mechanism. Nevertheless, studies have been conducted to compare the industry standard Mohr's casing wear test (which does utilize drilling mud) and the modified ASTM G77 test described herein. The evaluation shows a near perfect correlation (R₂˜1) between the casing wear measurements of both tests.

Applications:

The coating in one embodiment is suitable for use in hard bodies wear applications. In these applications, the material loss in coatings is typically caused by abrasive wear of the harder abrading particles. To reduce the material loss in this process, one should increase the hardness of the coating and/or increasing the amount of comparably hard particles (comparable as related to the abradable particles themselves) or phases within the coating. The alloys contain a sufficient amount of hard particles and display a sufficient hardness property for the protected equipment under these conditions.

The coating is also suitable for use in soft bodies wear applications, wherein the coating material wears away against a soft body under conditions of sliding wear. The material loss in the coating is primarily associated with the loss of soft materials due to contact and relative motion with the relatively harder material in the coating. In these applications, it is beneficial to limit the hardness of the coating material or reduce the amount of hard phases within the coating and decrease the overall coefficient of friction between the two materials. The controlled amount of hard phases in the coating minimizes material losses with the hard materials essentially machining away against the soft body contained within.

The alloys are particularly useful for oil & gas applications, e.g., for work pieces employed in subterraneous drilling operations as coating for drill stem assemblies, exposed outer surface of a bottom hole assembly, coatings for tubing coupled to a bottom hole assembly, coatings for casings, hardbanding on at least a portion of the exposed outer surface of the body, and as coatings for oil and gas well production devices as disclosed in

US Patent Publication No. 2011/0042069A1, the disclosure is included herein by reference in its entirety. Examples include devices for use in drilling rig equipment, marine riser systems, tubular goods, wellhead, formation and sandface completions, lift equipment, etc. Specific examples include drillpipe tool joints, drill collars, casings, risers, and drill strings. The coating can be on a least a portion of the inner surface of the work piece, at least a portion of the outer surface, or combinations thereof, preventing tool joint wear (due to the high inherent durability) and preventing casing wear (due to the minimal wear caused by these alloys on softer materials). The coatings provide protection in operations with wear from vibration (stick-slip and torsional) and abrasion during straight hole or directional drilling, allowing for improved rates of penetration and enable ultra-extended reach drilling with existing equipment.

In a tool joint application, the tool joint (intermediate hardness) comes into contact with sand and rock (high hardness) and the casing (low hardness). Under such conditions, the sand and rock wear away creating material loss and damage on the tool joint, whereas the tool joint wears away at the casing creating material loss and damage. The multiple wear interactions reduce the lifetime in the drill pipe (tool joint) and the casing. When used as a protective coating, the metal alloys effectively: a) minimize the loss of coating material caused by the harder abrading particles with an increased hardness of the coating and/or with an increase in the amount of comparably hard particles (comparable as related to the abradable particles themselves) or phases within the coating; and b) minimize the loss of material on the casing (soft coating) due to contact and relative motion with the relatively harder coating material, by limiting the hardness of the coating material of the tool joint with controlled amount of hard phases within the coating, thus decreasing the overall coefficient of friction between the two materials.

Besides the oil & gas industry, the alloys can also be used as coatings in may other industries, e.g., drilling, mining, quarrying, processing of minerals, and construction. In one embodiment, the alloys are used for structural members in building and bridges. The alloys can also be used for earth moving and dredging equipment and components such as bucket teeth, gravel pump parts, crusher hammers, conveyor chains, gear teeth, and metal to metal sliding parts in the industry.

The coating can be applied as raised (“proud”) or flush (“recessed”) hardbanding. The coating can be applied on used equipment, e.g., pipe with no previous hardbanding, or to be hardbanded on new work pieces. The coating can be deposited over pre-existing weld deposits, such as tungsten carbide deposits and many other previous hard-facing and hard-banding deposits. In one embodiment, the old hardbanding on the equipment is first removed before the application of the alloy.

### EXAMPLES

The following examples are intended to be non-limiting.

### Example 1

An alloy composition of Alloy 1 (Fe—82.68%, Cr—5%, Nb—4.3%, V—0.5%, C—0.8%, B—2.5%, Mo—(3%, Mn—0.5%, Ti—0.2%, and Si—0.5%) was produced in the form of a 1/16″ cored wire. The alloy was arc-welded onto a 6⅝″ outer diameter box 4137 alloy tool joint pre-heated to 500° F. The joint was rotated at a rotation rate of one full rotation every 2 min and 30 sec. The welding head was moved through the action of an oscillator, resulting in a weld bead approximately 1″ wide and 4/32″ thick. Three consecutive beads were made, one next to another to produce three adjacent 1″ beads for a total thickness of roughly 3″. The joint was allowed to cool to room temperature.

The microstructure of the weld bead was examined with optical scanning micrographs as shown in FIG. 2A for an unmodified image and FIG. 2B for a color modified image, highlighting the chromium enriched ferritic matrix (shown in black) from the hard particles (shown in white). The scale of the hard particles are shown in FIG. 3, which shows the ferritic matrix [501, 502] with embedded Nb carbide particles [503] and Mo borocarbide precipitates in eutectic phase [504]. As shown, the particles with a size of >100 nm are present in an amount of less than 15 vol %, with Nb carbide precipitates making up the bulk of the >100 nm particle volume fraction (over 90%).

### Example 2

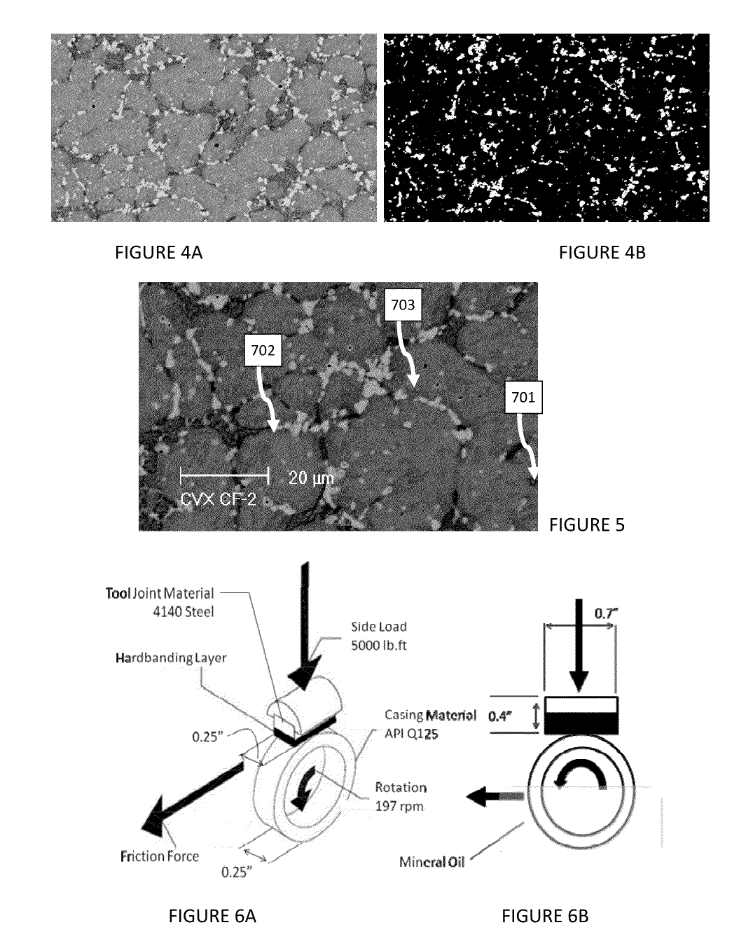

Example 1 was repeated with a different alloy composition, Alloy 2 (Fe—82.68%, Cr—5%, Nb—4.3%, V—0.5%, C—0.8%, B—2.5%, Mo—3%, Mn—0.5%, Ti—0.2%, and Si—0.5%). A well bead was produced with the microstructure as shown in FIG. 4A with an unmodified image, FIG. 4B with a color modified image, and FIG. 5 is an SEM detailing the specific phases in the bead: [701] as the ferritic matrix; [702] as chromium enriched ferritic matrix; and [703] as the niobium and tungsten borocarbide particle accounting for less than 15 volume % of the matrix.

From the Figures of Examples 1 and 2, it is determined that Mo and W exhibit similar effects on the microstructure of alloys, forming hard particles accounting for less than 15 volume % of the matrix.

### Example 3

A number of samples were constructed out of Alloys 1-8 by either welding or casting, and examined for carbide concentration and tested for hardness. The results of the tests are presented in Table 1.

TABLE 1

| Alloy | Carbide Concentration | Form | Hardness (R_{c}) |
|---|---|---|---|
| 1 | 9% | Weld | 55 |
| 2 | 9.4% | Weld | 52-55 |
| 3 | NM | Weld | 52-55 |
| 4 | NM | Weld | NM |
| 5 | 8.4% | Cast | 56-57 |
| 6 | 11.9% | Cast | 54-55 |
| 7 | 12.7% | Cast | 51 |
| 8 | 11.55% | Cast | 50 |

### Example 4

A wire was produced from Alloy 1 (Fe—82.68%, Cr—5%, Nb—4.3%, V—0.5%, C—0.8%, B—2.5%, Mo—3%, Mn—0.5%, Ti—0.2%, and Si—0.5%) and used as feedstock for a hardfacing onto a mild steel A36 substrate using a MIG welding system. A number of overlay samples were prepared from 6 alloy compositions as disclosed in US Patent Publication No. 2011/0068152 as comparables (samples A-F) with the compositions of:

A: Fe—82.95%, Cr—5%, Mn—1%, Nb—4.3%, V—0.5%, C—0.8%, B—1.75%, Mo—3%, Si—0.4%, Ti—0.3%;

B: Fe—83.45%, Cr—5%, Mn—1%, Nb—4.3%, V—0.5%, C—0.8%, B—1.25%, Mo—3%, Si—0.4%, Ti—0.3%;

C: Fe—88%, Cr—3%, Mn—1%, Nb—4.3%, V—0.5%, C—0.8%, B-1%, Mo—2%, Si—0.4%, Ti—0.3%;

D: Fe—76.62%, Cr—5.12%, Mn—1.1%, Nb—4.3%, V—2.7%, C-1.07%, B—0.82%, W—7.6%, Si—0.5%, Ti—0.2%;

E: Fe—73.11%, Cr—5.75%, Mn—0.3%, Nb—4.3%, V—2.78%, C-0.85%, B—0.94%, W—10.8%, Si—0.61%, Ti—0.2%;

F: Fe—84%, Cr—3%, Mn—1%, Nb—3%, V—1.4%, C—0.8%, B-1.1%, W—5%, Si—0.4%, Ti—0.3%.

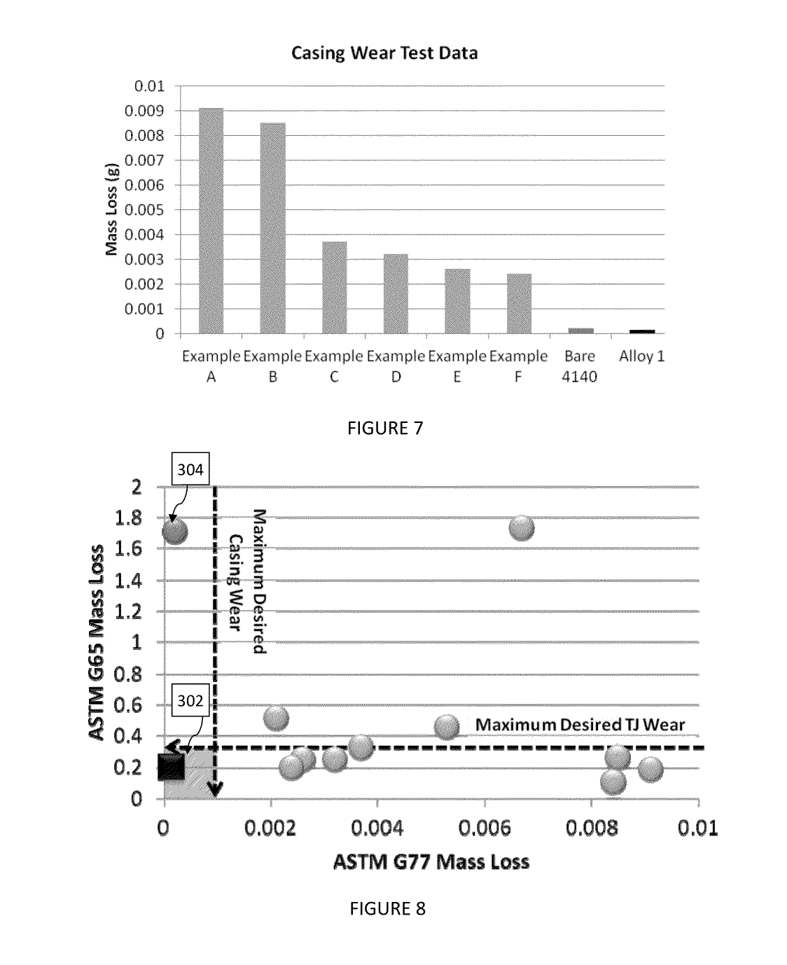

Casing wear comparison was conducted using the modified ASTM G77 wear test on samples prepared from Comparative Samples A-F, Alloy 1, and bare 4140 alloy steel. The results are shown in FIG. 7 with Alloy 1 having a mass loss of well below 0.001 g.

Tool joint wear evaluation per ASTM G65 was also conducted on the samples. Results of the test are shown in FIG. 8. The black square in the plot indicates that Alloy 1 provides the optimal protection with minimal mass loss per ASTM G65 and modified ASTM G77 [302], as compared to bare 4140 alloy steel [304] and Comparative Samples A-F with ASTM G77 mass loss well above the maximum desired casing wear of 0.001 g per modified ASTM G77.

For the purposes of this specification and appended claims, unless otherwise indicated, all numbers expressing quantities, percentages or proportions, and other numerical values used in the specification and claims, are to be understood as being modified in all instances by the term “about.” Accordingly, unless indicated to the contrary, the numerical parameters set forth in the following specification and attached claims are approximations that may vary depending upon the desired properties sought to be obtained by the present invention. It is noted that, as used in this specification and the appended claims, the singular forms “a,” “an,” and “the,” include plural references unless expressly and unequivocally limited to one referent. As used herein, the term “include” and its grammatical variants are intended to be non-limiting, such that recitation of items in a list is not to the exclusion of other like items that can be substituted or added to the listed items.

This written description uses examples to disclose the invention, including the best mode, and also to enable any person skilled in the art to make and use the invention. The patentable scope is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims. All citations referred herein are expressly incorporated herein by reference.

1. A work piece capable of withstanding service abrasion, having at least a portion of the work pieced surface protected by a deposited layer comprising an Fe-based alloy composition;
wherein the deposited layer exhibits a hardness of at least 50 R_{c}, a wear rate of less than 0.5 grams of mass loss as measured according to ASTM G65-04-Procedure A, a wear rate on a contacting secondary body comprising carbon steel of less than 0.005 grams of carbon steel as measured according to modified ASTM G77 wear test.

2. The work piece of claim 1, wherein the Fe-based alloy composition has in wt. %: at least one of Cr and Nb of less than 6% each with a total concentration of Cr and Nb of less than 11%, at least one of Mo and W in an amount of up to 8% each, at least one of B, C, and Si in an amount of 0.5 to 4%, balance iron, including impurities as trace elements.

3. The work piece of claim 1, wherein the deposited layer exhibits a hardness of at least 55 R_{c}.

4. The work piece of claim 1, wherein the deposited layer exhibits a wear rate of less than 0.35 grams of mass loss as measured according to ASTM G65-04-Procedure A

5. The work piece of claim 1, wherein the deposited layer exhibits a wear rate on a contacting secondary body comprising carbon steel of less than 0.001 grams of carbon steel as measured according to modified ASTM G77 wear test.

6. The work piece of claim 1, wherein the deposited layer forms an iron matrix comprising embedded hard particles having an average particle size ranging from 100 nm to 20 μm.

7. The work piece of claim 1, wherein the deposited layer forms an iron matrix comprising embedded hard particles having an average particle size ranging from 1 to 15 nm.

8. The work piece of claim 1, wherein the deposited layer forms an iron matrix comprising embedded hard particles in an amount of less than 15 vol. %.

9. The work piece of claim 8, wherein the deposited layer forms an iron matrix comprising embedded hard particles in an amount of less than 10 vol. %.

10. The work piece of claim 1, wherein the deposited layer forms an iron matrix comprising embedded boride, carbide, and borocarbide particles.

11. The work piece of claim 2, wherein the deposited layer comprises an alloy composition having in wt. %: Cr (0-6%), Mn (0-6%), Nb (2-6%), V (0-4%), C (0.25-2%), B (0.75-3%), at least one of Mo and W (0-8% each) and up to 15% total, Ti (0-1%), Si (0-1%), with total concentration of Cr and Nb of up to 11%, total concentration of B, C and Si of up to 4%; and balance iron including impurities as trace elements.

12. The work piece of claim 2, wherein the deposited layer comprises an alloy composition having in wt. %: Cr (0-6%), Mn (0-1%), Nb (4-6%), V (0.5-3%), C (0-1%), B (1-3%), at least one of Mo and W of 3-8% each and up to 15% total, Ti (0-0.25%), and Si (0-0.75%), with total concentration of Cr and Nb of up to 11%, total concentration of B, C and Si of up to 4%; and balance iron including impurities as trace elements.

13. The work piece of claim 1, wherein the layer is deposited by any of thermal spray coating, weld-overlay, laser cladding, and combinations thereof.

14. The work piece of claim 12, wherein the layer is deposited onto at least a portion of the work piece surface by any of laser welding, shielded metal arc welding (SMAW), stick welding, plasma transfer arc welding (PTAW), gas metal arc-welding (GMAW), metal inert gas welding (MIG), submerged arc welding (SAW), open arc welding (OAW), and combinations thereof.

15. The work piece of claim 1, wherein the deposited layer has a microstructure containing a plurality of hard particles in an iron matrix, wherein the microstructure has a hardness variation of less than 50% as measured using a Vickers indenter between the hard particles and the matrix.

16. The work piece of claim 15, wherein the hardness variation is less than 25%.

17. The work piece of claim 1, wherein the work piece for use in any of drilling rig equipment, down hole components, marine riser systems, tubular goods, wellhead, formation equipment, sandface completions, and lift equipment.

18. The work piece of claim 16, wherein the work piece is a drill pipe or a tool joint.

19. The work piece of claim 1, wherein the work piece is any of earth moving equipment, dredging equipment, bucket teeth, gravel pump parts, crusher hammers, conveyor chains, gear teeth, and sliding parts.

20. The work piece of claim 1, for protecting a drill pipe for use in oil and gas services.

21. A hardbanding for protecting a work piece in an abrasive environment, wherein the hardbanding comprises:
a layer comprising an alloy composition having in wt. %: Cr (0-6%), Nb (2-6%), Mn (0-6%), V (0-4%), C (0.25-2%), B (0.75-3%), at least one of Mo and W (3-8% each) and up to 15% total, Ti (0-1%), Si (0-1%), with total concentration of Cr and Nb of up to 11%, total concentration of B, C and Si of up to 4%; and balance iron including impurities as trace elements,
the layer is welded onto at least a portion of the work piece by any of the welding techniques such as for example and not limited to laser welding, shielded metal arc welding (SMAW), stick welding, plasma transfer arc welding (PTAW), gas metal arc-welding (GMAW), metal inert gas welding (MIG), submerged arc welding (SAW), open arc welding (OAW), and combinations thereof;
wherein the welded layer exhibits a hardness of at least 50 R_{c}, a wear rate of less than 0.5 grams of mass loss as measured according to ASTM G65-04-Procedure A, a wear rate on a contacting secondary body comprising carbon steel of less than 0.005 grams of carbon steel as measured according to modified ASTM G77 wear test.
